(19) United States
(12) Patent Application Publication
(10) Pub. No.: US 2025/0382723 A1
(43) Pub. Date: Dec. 18, 2025

(54) NICKEL SUBSTRATE, AND METHOD FOR PRODUCING DIAMOND SUBSTRATE USING THE SAME

(71) Applicants: National University Corporation Kanazawa University, Kanazawa-shi (JP); Shin-Etsu Chemical Co., Ltd., Tokyo (JP)

(72) Inventors: Norio TOKUDA, Kanazawa-shi (JP); Satoshi YAMASAKI, Kanazawa-shi (JP); Tsubasa MATSUMOTO, Kanazawa-shi (JP); Naoki MIKOSHIBA, Kanazawa-shi (JP); Taiga ASAI, Echizen-shi (JP)

(73) Assignees: National University Corporation Kanazawa University, Kanazawa-shi (JP); Shin-Etsu Chemical Co., Ltd., Tokyo (JP)

(21) Appl. No.: 19/291,577

(22) Filed: Aug. 5, 2025

Related U.S. Application Data
(63) Continuation of application No. PCT/JP2023/041736, filed on Nov. 21, 2023.

(30) Foreign Application Priority Data
Feb. 10, 2023 (JP) 2023-019115

(51) Int. Cl. C30B 29/04; C30B 15/30; C30B 25/18; C30B 33/12

(52) U.S. Cl. CPC C30B 29/04; C30B 15/30; C30B 25/186; C30B 33/12

(57) ABSTRACT

An object is to provide a nickel substrate to be used for obtaining a large-diameter diamond substrate, and to provide a method for producing a diamond substrate using the same. Provided is a nickel substrate to be used for heteroepitaxially growing a diamond layer, and the nickel substrate consists of a single crystal, and has a (111) crystal plane on a surface thereof.

### CROSS REFERENCE TO RELATED APPLICATIONS

This application is a continuation of International Patent Application No. PCT/JP2023/041736, having an international filing date of Nov. 21, 2023, which designated the United States, the entirety of which is incorporated herein by reference. Japanese Patent Application No.2023-019115 filed on Feb. 10, 2023 is also incorporated herein by reference in its entirety.

### BACKGROUND OF THE INVENTION

The present disclosure relates to a nickel substrate to be used for heteroepitaxially growing a diamond layer, and a method for producing a diamond substrate using this nickel substrate.

Diamond is a power semiconductor material, and is expected also as a quantum material operating at room temperature.

While diamond possesses a larger bandgap, higher insulation properties, and greater thermal conductivity than wide bandgap semiconductors such as SiC and GaN, it is technically difficult to obtain a freestanding diamond substrate of 4 inches or more.

For example, German startup, Audiatec has developed a technology to grow single crystal diamond using microwave plasma CVD on an Ir layer, which is formed via YSZ (yttria stabilized zirconia) on a Si substrate, and is now selling a diamond single crystal.

This is because while large-diameter Ir substrates have not been obtained, large-diameter Si substrates of 6 inches or more can be obtained. As illustrated in a physical property comparison table of FIG. 5, there is a significant difference in lattice constant between Si and diamond, and hence, considerable strain is caused by lattice mismatch, and therefore, it is necessary to form an Ir layer via a YSZ layer to mitigate the strain with a diamond layer subsequently grown heteroepitaxially thereon.

In contrast, a Ni substrate has lattice mismatch with diamond of only about 1% at 20° C., and has greater thermal expansion than diamond, and hence it can be predicted that by increasing the temperature for the heteroepitaxial growth of a diamond layer, the lattice mismatch with the diamond layer can be further reduced.

Focusing on this point, the present inventors have proposed a method for producing diamond using a nickel substrate (JP-B-6561402).

In recent years, as described in “Crystal growth of 8 inch diameter Ni single crystal for GaN substrate”, Kazuya Takahashi et al., Abstracts of 81st Japan Society of Applied Physics Autumn Meeting, 2020, 8p-Z14-3, for example, large-diameter Ni substrates of 4 inches, 6 inches, and even larger have begun to be proposed, and therefore, attempts have made to grow a diamond layer using such a large-diameter single crystal Ni substrate based on the present disclosure described in JP-B-6561402, but only an amorphous carbon layer or a polycrystalline diamond layer with low orientation could be formed on the large-diameter single-crystal Ni substrate as it was.

### BRIEF DESCRIPTION OF THE DRAWINGS

FIG. 1A illustrates a surface appearance and EBSD (electron backscatter diffraction) analysis results of a Ni base material immediately after purchase (Comparative Example), and FIG. 1B illustrates a surface appearance and EBSD analysis results of a Ni substrate obtained after removing a deteriorated layer (Present disclosure).

FIG. 2 illustrates analysis results of the deteriorated layer by EDS (energy dispersive X-ray spectroscopy).

FIG. 3 illustrates an example of film formation with a CVD apparatus using a Ni base material having a deteriorated layer thereon.

FIG. 4 illustrates an example of heteroepitaxial growth of a diamond layer using the Ni substrate according to the present disclosure.

FIG. 5 is a comparison table of physical properties of diamond, Si, Ir, and Ni.

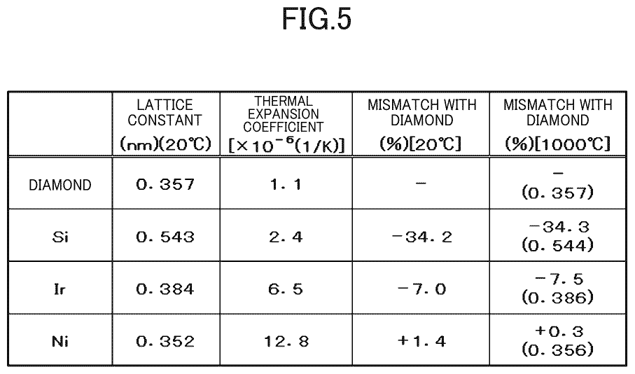

### DETAILED DESCRIPTION

The following disclosure provides many different embodiments, or examples, for implementing different features of the provided subject matter. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Further, when a first element is described as being “connected” or “coupled” to a second element, such description includes embodiments in which the first and second elements are directly connected or coupled to each other, and also includes embodiments in which the first and second elements are indirectly connected of coupled to each other with one or more other intervening elements in between.

An object of the present disclosure is to provide a nickel substrate for obtaining a large-diameter diamond substrate, and a method for producing a diamond substrate using the same.

In accordance with one of some embodiments, there is provided a nickel substrate to be used for heteroepitaxially growing a diamond layer, the nickel substrate consisting of a single crystal, and having a (111) crystal plane on a surface thereof.

According to the research conducted by the present inventors, it has been revealed that a deteriorated layer forms on a surface of a single crystal Ni substrate during surface polishing process and the like, and hence a normal (111) crystal plane does not appear on the surface.

In JP-B-6561402, the surface of the polycrystal nickel base material is cleaned simply by a hydrogen plasma treatment for about 30 minutes, but it has been revealed that when such a condition is employed, a deteriorated layer formed on a polished surface of a single crystal nickel base material cannot be removed.

Based on the research of the present inventors, it has been revealed that to make a normal (111) crystal plane appear on the surface, it is necessary to perform a hydrogen plasma treatment with the base material heated to 1000° C. or higher using a CVD apparatus.

In such a single crystal Ni substrate, the (111) crystal plane can be obtained by performing a hydrogen plasma treatment to remove a surface layer of a base material, the base material being obtained by slicing a single crystal nickel ingot in the <111> orientation, followed by surface-polishing.

Here, the single crystal nickel ingot may be a single crystal bulk material produced by Czochralski (CZ) method in which a seed crystal is dipped into a melt and then pulled up while rotating the crystal.

In accordance with one of some embodiments, there is provided a method for producing a diamond substrate, comprising forming, using a CVD apparatus, a carbon solid solution and a diamond nucleus on a surface of the nickel substrate according to claim 1; and epitaxially growing a diamond layer.

A technique using a single crystal nickel substrate of the present disclosure for heteroepitaxially growing a diamond layer on a surface thereof can refer to the process described in JP-B-6561402.

A single crystal Ni substrate according to the present disclosure has a (111) crystal plane on its surface, and hence, a highly oriented diamond layer can be heteroepitaxially grown by using the substrate.

In particular, by using a large-diameter single crystal Ni substrate of 4 inches or larger, large-diameter diamond substrates of 4 inches, 6 inches, and even 7 inches or larger can be obtained.

Exemplary embodiments are described below. Note that the following exemplary embodiments do not in any way limit the scope of the content defined by the claims laid out herein. Note also that all of the elements described in the present embodiment should not necessarily be taken as essential elements.

A single crystal nickel base material was obtained by slicing a single crystal Ni bulk material produced by a CZ method, and surface-polishing the resultant. A sample having a deteriorated layer on a surface of the single crystal nickel base material, and another sample from which this deteriorated layer had been removed by a hydrogen plasma treatment using a CVD apparatus were subjected to a heteroepitaxial growth test, which will now be described.

Herein, the sample having the deteriorated layer on its surface is referred to as a nickel base material, and the sample with the deteriorated layer removed is referred to as a nickel substrate for distinguishing these.

A surface of a purchased single crystal nickel base material was cleaned with acetone and ethanol, followed by a 10-minute ultrasonic cleaning using ultrapure water, and thus, a comparative example was obtained. A present disclosure sample was obtained by further performing a hydrogen plasma treatment using a CVD apparatus after the cleaning, so as to be comparatively evaluated.

The evaluation was conducted by employing the following combination of conditions for the hydrogen plasma treatment:
(1) Input power (W): 1250, 1400, 1520
(2) Pressure (kPa): 3
(3) Hydrogen flow rate (sccm): 50
(4) Treatment time (hour): 0.5 h, 1.5 h, 3h, 5h

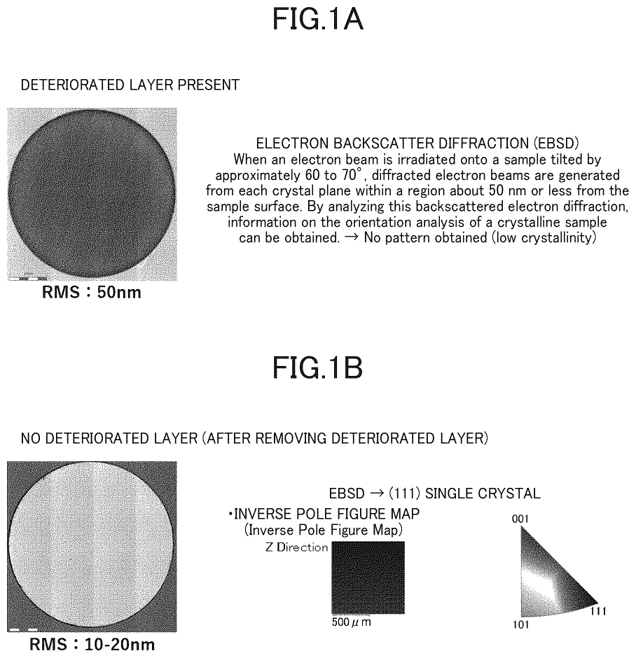

FIGS. 1A and 1B illustrate a surface appearance and EBSD (electron backscatter diffraction) analysis results of the Ni base material and the nickel substrate.

FIG. 1A illustrates the result of the comparative example having been subjected only to ultrasonic cleaning, and FIG. 1B illustrates the result of the present disclosure sample obtained by removing the deteriorated layer from the surface of the base material by the hydrogen plasma treatment.

The comparative example having the deteriorated layer had surface roughness (RMS) of about 50 nm, and was found, by the EBSD (electron backscatter diffraction) analysis, to have no crystal pattern on the surface thereof, and thus was revealed to be poor in crystallinity.

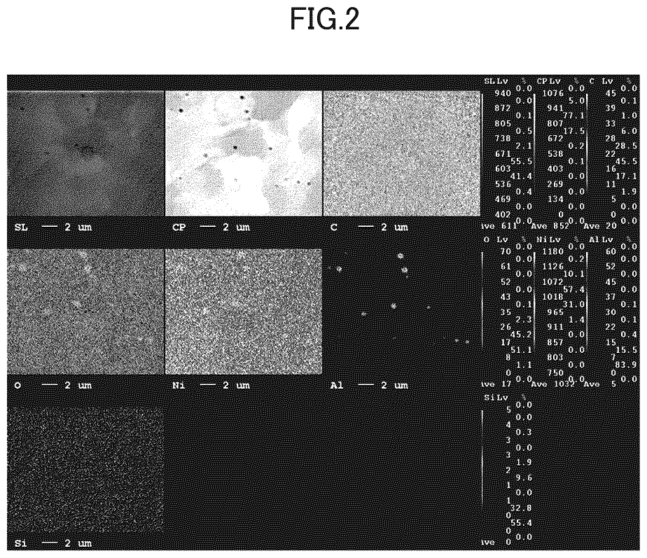

Results of surface analysis by energy dispersive X-ray spectroscopy (EDS) are illustrated in FIG. 2.

Impurities were present on the surface, and Al oxides presumed to be a component of an abrasive were also present on the surface.

In contrast, in the sample having been subjected to the hydrogen plasma treatment with an input power of 1250 W for 0.5 hours, the temperature of the base material reached 1230° C., and a (111) crystal plane appeared on the surface.

There partially was, however, a deteriorated layer.

Under conditions of the input power of 1400 W and 0.5 hours (temperature of the base material: 1300° C.), a uniform (111) crystal plane was obtained.

When the hydrogen plasma treatment was conducted under conditions of the input power of 1400 W and 1.5 hours, 3 hours, or 5 hours, the temperature of the base material was 1300 to 1350° C., and a uniform (111) crystal plane was obtained in all the cases. When conditions of the input power of 1520 W and 0.5 hours were employed, the temperature of the base material was 1300° C., and a uniform (111) crystal plane was formed also in this case.

Besides, the surface roughness (RMS) was at a level of 10 to 20 nm.

From these findings, it was revealed that the temperature of the base material is an important factor for removing the deteriorated layer.

For removing the deteriorated layer present on the surface of a single crystal nickel base material, the temperature of the base material is at least 1200° C. or more, suitably 1200 to 1350° C., and preferably 1300 to 1350° C.

Besides, the input power is 1250 to 1520 W, and preferably in a range of 1400 to 1520 W.

FIG. 1B illustrates, for reference, an EBSD image of a sample prepared under conditions of the input power of 1400 W and 5 hours, wherein a (111) crystal plane appeared uniformly on the surface.

Next, the nickel base material having the deteriorated layer on the surface thereof, and the nickel substrate from which the deteriorated layer had been removed were used for conducting film formation evaluation using a CVD apparatus.

As a film formation method, a bias treatment (BEN: bias enhanced nucleation) was performed using 2.45 GHz microwaves under the following conditions:
(1) Input power (W): 700
(2) Pressure (kPa): 10
(3) Hydrogen flow rate (sccm): 50
(4) Methane concentration (%): 10
(5) Applied voltage (V): −350
(6) Treatment time (min): 25

Thus, a diamond nucleus was formed, and then a diamond layer was grown under the following conditions:
(1) Input power (W): 700
(2) Pressure (kPa): 10
(3) Hydrogen flow rate (sccm): 100
(4) Methane concentration (%): 2
(5) Treatment time (hour): 5

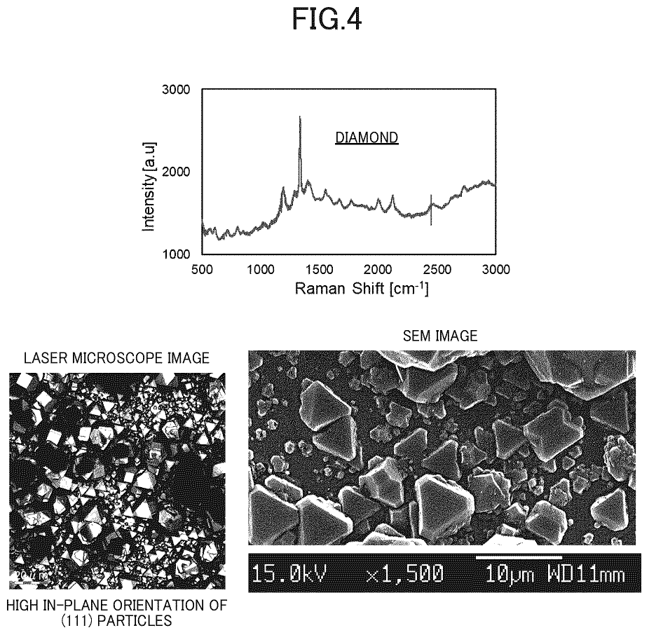

A Raman spectrum obtained with a Raman spectrophotometer, a laser microscope image, and an SEM image of a diamond layer obtained by the above-described process are illustrated in FIG. 4.

From the Raman spectrum, the formation of diamond was confirmed, and from the laser microscope image and SEM image, high in-plane orientation of (111) particles was revealed.

Next, the nickel base material from which the deteriorated layer had not been removed was used to perform the processes similar to those described above.

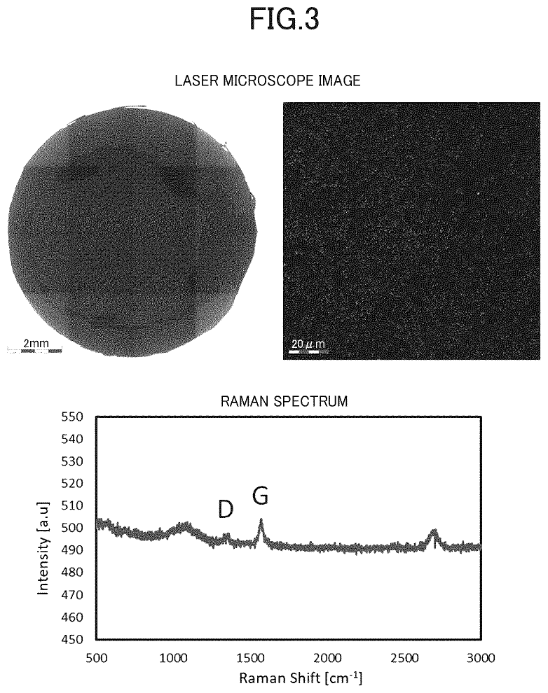

As a result, as illustrated in FIG. 3 of the external appearance, laser microscope image, and Raman spectrum, a graphite layer was formed, and no diamond layer could be confirmed.

Referring to these findings, by removing a deteriorated layer present on the surface of a single crystal nickel base material under specific conditions, a highly oriented diamond layer can be heteroepitaxially grown.

Although only some embodiments of the present invention have been described in detail above, those skilled in the art will readily appreciate that many modifications are possible in the embodiments without materially departing from the novel teachings and advantages of this invention. Accordingly, all such modifications are intended to be included within scope of this invention.

According to the present disclosure, a large-diameter single crystal Ni substrate can be obtained, based on which a large-diameter diamond substrate can be obtained.

1. A nickel substrate to be used for heteroepitaxially growing a diamond layer, the nickel substrate consisting of a single crystal, and having a (111) crystal plane on a surface thereof.

2. A method for producing the nickel substrate according to claim 1, comprising obtaining the (111) crystal plane by performing a hydrogen plasma treatment to remove a surface layer of a base material, the base material being obtained by slicing a single crystal nickel ingot in <111> orientation, followed by surface-polishing.

3. The method for producing the nickel substrate according to claim 2, wherein the single crystal nickel ingot is a single crystal bulk material produced by Czochralski (CZ) method in which a seed crystal is dipped into a melt and then pulled up while rotating the crystal.

4. The method for producing the nickel substrate according to claim 2, wherein the hydrogen plasma treatment is performed using a CVD apparatus by heating the base material to a temperature of 1200° C. or higher.

5. The method for producing the nickel substrate according to claim 4, wherein the hydrogen plasma treatment is performed with an input power of 1250 to 1520 W to the CVD apparatus.

6. A method for producing a diamond substrate, comprising forming, using a CVD apparatus, a carbon solid solution and a diamond nucleus on a surface of the nickel substrate according to claim 1; and epitaxially growing a diamond layer.
